(19) United States
(12) Patent Application Publication
(10) Pub. No.: US 2008/0182413 A1
(43) Pub. Date: Jul. 31, 2008

(54) SELECTIVE CHEMISTRY FOR FIXED ABRASIVE CMP

(76) Inventors: GREGORY E. MENK, Pleasanton, CA (US); Robert L. Jackson, San Jose, CA (US); Garlen C. Leung, San Jose, CA (US); Gopalakrishna B. Prabhu, San Jose, CA (US); Peter McReynolds, San Mateo, CA (US); Anand N. Iyer, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/839,048

(22) Filed: Aug. 15, 2007

Related U.S. Application Data
(60) Provisional application No. 60/822,625, filed on Aug. 16, 2006.

(51) Int. Cl. H01L 21/461; C09K 13/00

(52) U.S. Cl. 438/693; 252/79.1; 257/E21.304

(57) ABSTRACT

Methods and compositions for planarizing a substrate surface with selective removal rates and low dishing are provided. One embodiment provides a method for selectively removing a dielectric disposed on a substrate having at least a first and a second dielectric material disposed thereon. The method generally includes positioning the substrate in proximity with a fixed abrasive polishing pad, dispensing an abrasive free polishing composition having at least one organic compound and a surfactant therein between the substrate and the polishing pad, and selectively polishing the second dielectric material relative to the first dielectric material.

### BACKGROUND OF THE INVENTION

1. Field of the Invention

Embodiments of the invention generally relate to planarization of semiconductor devices and to methods and compositions for material removal using polishing techniques.

2. Description of the Related Art

Reliably producing sub-half micron and smaller features is one of the key technologies for the next generation of very large-scale integration (VLSI) and ultra large-scale integration (ULSI) of semiconductor devices. However, the shrinking dimensions of interconnects in VLSI and ULSI technology has placed additional demands on the processing capabilities. The multilevel interconnects that lie at the heart of this technology require precise processing of high aspect ratio features, such as vias, contacts, lines, and other interconnects. Reliable formation of these interconnects is important to VLSI and ULSI success and to the continued effort to increase circuit density and quality of individual substrates and die.

Multilevel interconnects are formed by the sequential deposition and removal of materials from the substrate surface to form features therein. As layers of materials are sequentially deposited and removed, the uppermost surface of the substrate may become non-planar across its surface and require planarization prior to further processing. Planarizing a surface, or “polishing” a surface, is a process where material is removed from the surface of the substrate to form a generally even, planar surface. Planarization is useful in removing excess deposited material and in removing undesired surface topography and surface defects, such as rough surfaces, agglomerated materials, crystal lattice damage, scratches, and contaminated layers or materials to provide an even surface for subsequent processing.

Chemical mechanical planarization, or chemical mechanical polishing (CMP), is a common technique used to planarize substrates. In conventional CMP techniques, a substrate carrier or polishing head is mounted on a carrier assembly and positioned in contact with a polishing media in a CMP apparatus. The carrier assembly provides a controllable pressure to the substrate urging the substrate against the polishing media. The substrate and polishing media are moved in a relative motion to one another.

A polishing composition is provided to the polishing media to effect chemical activity in removing material from the substrate surface. The polishing composition may contain abrasive material to enhance the mechanical activity between the substrate and polishing media. Thus, the CMP apparatus effects polishing or rubbing movement between the surface of the substrate and the polishing media while dispersing a polishing composition to effect both chemical activity and mechanical activity. The chemical and mechanical activity removes excess deposited materials as well as planarizing a substrate surface.

Chemical mechanical polishing may be used in the fabrication of shallow trench isolation (STI) structures. STI structures may be used to separate transistors and components of a transistor, such as source/drain junctions or channel stops, on a substrate surface during fabrication. STI structures can be formed by depositing a series of dielectric materials and polishing the substrate surface to remove excess or undesired dielectric materials. An example of a STI structure includes depositing a silicon nitride layer on an oxide layer formed on a silicon substrate surface, patterning and etching the substrate surface to form a feature definition, depositing a silicon oxide fill of the feature definitions, and polishing the substrate surface to remove excess silicon oxide to form a feature. The silicon nitride layer may perform as a barrier layer, a hard mask during etching of the features in the substrate and/or as a polishing stop during subsequent polishing processes. Such STI fabrication processes require polishing the silicon oxide layer to the silicon nitride layer with a minimal amount of silicon nitride removed during the polishing process in order to prevent damaging of the underlying materials, such as oxide and silicon.

The STI substrate is typically polished using conventional, abrasive-free, polishing media and an abrasive containing polishing slurry. However, polishing STI substrates with conventional polishing articles and abrasive containing polishing slurries has been observed to result in overpolishing of the substrate surface and forming recesses in the STI features and other topographical defects such as microscratches on the substrate surface. This phenomenon of overpolishing and forming recesses in the STI features is referred to as dishing. Dishing is highly undesirable because dishing of substrate features may detrimentally affect device fabrication by causing failure of isolation of transistors and transistor components from one another resulting in short-circuits. Additionally, overpolishing of the substrate may also result in nitride loss and exposing the underlying silicon substrate to damage from polishing or chemical activity, which detrimentally affects device quality and performance.

FIGS. 1A-1C are schematic diagrams illustrating the phenomena of dishing and nitride loss. FIG. 1A shows an example of a patterned STI substrate with a substrate 10, having a thermal oxide layer 15 disposed thereon, a polishing/etch stop layer, such as silicon nitride layer 20, disposed on the thermal oxide layer 15, and patterned to have feature definitions 35. The feature definitions 35 are then filled with a dielectric fill material 30, such as a silicon oxide material, with excess dielectric fill material 40 formed over the feature definitions 35 and silicon nitride layer 20.

FIG. 1B illustrates the phenomena of dishing observed with polishing by conventional techniques to remove the excess dielectric fill material 40. During polishing of the silicon oxide material 30 to the silicon nitride layer 20, the silicon oxide material 30 may be overpolished to remove any residual dielectric fill material 30, which may result in surface defects, such as recesses 45, formed in the dielectric fill material 30 in the feature definitions 35. The amount of dishing 50 from the desired amount of dielectric fill material 30 in the feature definitions 35 is represented by dashed lines.

FIG. 1C illustrates nitride loss from the surface of the silicon nitride layer 20 from excess polishing of the substrate surface with conventional polishing processes. Silicon nitride loss may take the form of excess removal of silicon nitride, or “thinning” of the silicon nitride layer, from the desired amount of silicon nitride 60. Silicon nitride loss may also lead to premature exposure of the thermal oxide layer 15 and substrate 10. The silicon nitride loss may render the silicon nitride layer 20 unable to prevent or limit damage to or contamination of the underlying substrate material during polishing or subsequent processing.

STI polishing with fixed-abrasive polishing articles have shown reduced dishing and improved polishing uniformity compared with conventional slurry polishing processes. A fixed-abrasive polishing article generally contains fixed-abrasive particles held in a containment media, or binder, which provides mechanical activity to the substrate surface, along with a plurality of geometric abrasive composite elements adhered to the containment media. However, conventional fixed-abrasive polishing processes have an inherently low removal rate of oxide material thereby increasing polishing times and reducing substrate throughput. Increased processing time may also occur in conventional deposition processes that use excess material deposition on the substrate surface, referred to as overfill, to ensure fill of features formed in the substrate surface.

Several approaches have been examined for limiting the extent of oxide overfill in forming STI features for improved processing throughput. One approach includes using multiple deposition steps, for example high density plasma chemical vapor deposition (HDP CVD) and etching steps to deposit, etch back, and re-fill substrate features. Another approach uses a sputter or etching process to thin the overfill deposited on the substrate surface. Other approaches include using a post deposition wet etch process to etch the oxide film so that there is still topography remaining for use with fixed-abrasive polishing articles. However, these processes have been observed to increase integration complexity and also have increased processing times and reduced substrate throughput.

Therefore, there exists a need for a method and related polishing apparatus, which facilitates the removal of dielectric materials with minimal or reduced dishing and minimal or reduced loss of underlying materials.

### SUMMARY OF THE INVENTION

Embodiments of the present invention generally provide methods and compositions for planarizing a substrate surface with selective removal rates and low dishing.

One embodiment provides a method for selectively removing a dielectric disposed on a substrate having a first dielectric material and a second dielectric material disposed thereon. The method generally includes positioning the substrate in proximity with a fixed abrasive polishing pad, dispensing an abrasive free polishing composition having at least one organic compound and at least one polishing enhancement compound therein between the substrate and the polishing pad, and selectively polishing the second dielectric material relative to the first dielectric material. In one embodiment, the second dielectric material is removed at a higher removal rate than the first dielectric material.

Another embodiment provides a method for processing a substrate to selectively remove an oxide material disposed on a nitride material. The method generally includes positioning the substrate in proximity with a fixed abrasive polishing pad, dispensing an abrasive free polishing composition having at least one organic compound, at least one surfactant, at least one pH adjusting agent, and deionized water, between the substrate and the polishing pad, and removing the oxide material and nitride material at a removal rate ratio of the oxide material to the nitride material between about 10:1 or greater.

Another embodiment provides an abrasive free composition for removing dielectric materials using a fixed abrasive polishing pad. In one embodiment, the composition initially consists of at least one organic compound, at least one polishing enhancement compound, at least one pH adjusting agent, and deionized water. In one embodiment, the at least one polishing enhancement compound comprises a surfactant.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C are schematic diagrams illustrating the phenomena of dishing and nitride loss;

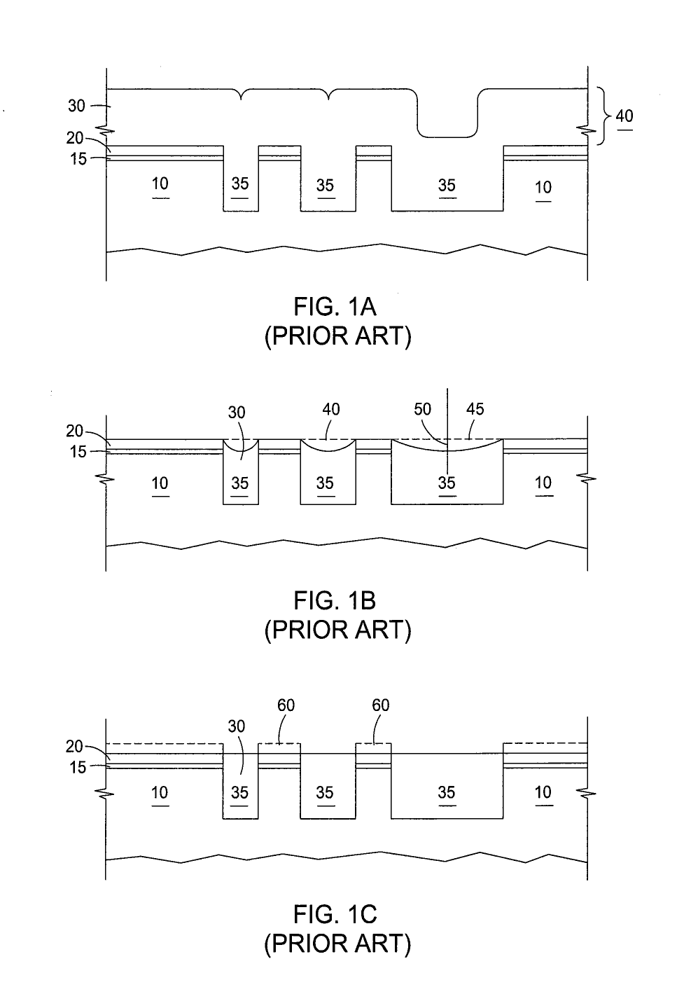

FIG. 2 is a schematic view of a chemical mechanical polishing apparatus;

FIG. 3 is a flow chart illustrating the processing steps according to one embodiment of the invention;

FIGS. 4A and 4B are schematic diagrams illustrating one embodiment of polishing a substrate by the methods described herein; and

FIG. 5 depicts a plot depicting oxide removal rate as a function of polish pressure for an L-proline/KOH polish fluid and a L-proline/KOH polish fluid to which about 0.05 wt. % of a fluorosurfactant has been added.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the invention will be described below in reference to a planarizing process and composition that can be carried out using chemical mechanical polishing process equipment, such as the Applied Reflexion® LK CMP System, the Applied Reflexion® LK Tungsten CMP System, the Applied Reflexion® LK ECMP System, the Applied Reflexion® LK Copper CMP System, and the Applied Reflexion® LK STI CMP, all of which are available from Applied Materials, Inc., of Santa Clara, Calif. In addition, any system enabling chemical mechanical polishing using the methods or compositions described herein can be used to advantage. Examples of other suitable polishing apparatuses include the Applied Mirra Mesa® CMP System also available from Applied Materials, Inc. of Santa Clara, Calif. The following apparatus description is illustrative and should not be construed or interpreted as limiting the scope of the invention.

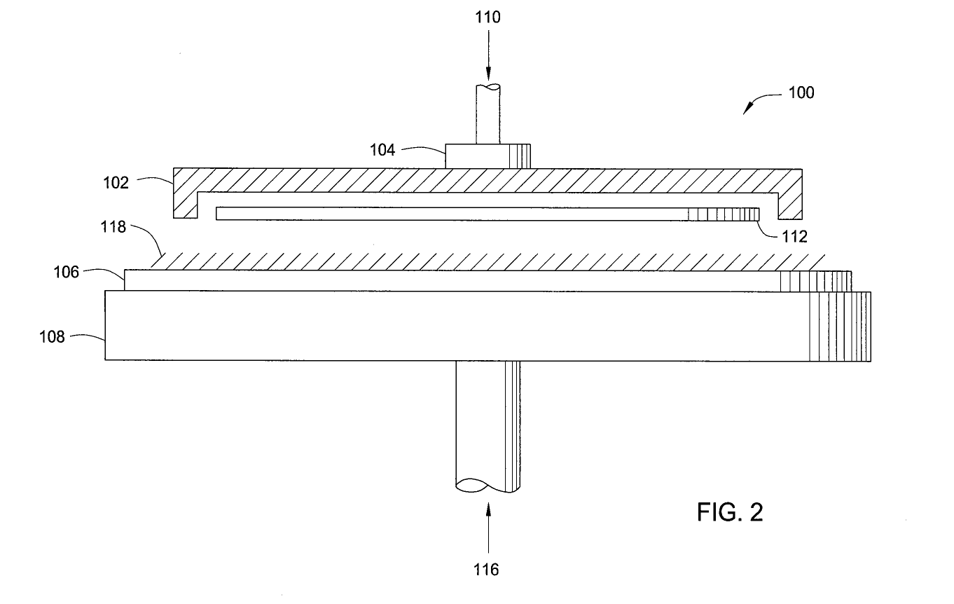

FIG. 2 is a schematic view of a CMP apparatus 100. The CMP apparatus 100 generally includes a polishing head 102, a polishing platen 108, and a polishing pad 106 disposed on the polishing platen 108. The polishing head 102 is capable of holding a substrate 112 thereon. The polishing platen 108 may be a linear web, a linear belt platen, or a rotatable platen. CMP systems may further include a carousel, at least one polishing head assembly 104 suspended from the carousel to hold the polishing head 102, and a positioning member coupled to the carousel to move the carousel and position the polishing head assembly 104 over the platen. The polishing head assembly 104 provides a controllable pressure 110 to the substrate 112 urging the substrate 112 against the polishing pad 106. Examples of the polishing pad 106 that may be used herein is a fixed abrasive polishing pad such as a M3100 SlurryFree™ CMP Fixed Abrasive Pad from 3M of St. Paul, Minn., which uses cerium oxide as abrasive articles, and the M3152 SlurryFree™ CMP Fixed Abrasive Pad which is also available from 3M. Fixed abrasive material generally includes a plurality of abrasive elements disposed on a flexible backing. In one embodiment, the abrasive elements are comprised of geometric shapes formed from abrasive particles suspended in a polymer binder. The polishing material may be in either pad or web form.

The CMP apparatus 100 effects a polishing or rubbing movement between the surface of the substrate 112 and the polishing pad 106 by applying an external force 116 between them either linearly or in rotationally while dispensing a polishing composition 118 or slurry with or without abrasive particles in order to effect both chemical and mechanical activities.

### Chemical Mechanical Polishing Process and Composition

Embodiments of the invention include CMP processes and compositions comprised of organic compounds, for example, amino acids, and polishing enhancement compounds, for example, surfactants. In one embodiment, a method of processing a substrate having an oxide material disposed on a nitride material is provided. The method includes positioning the substrate in proximity with a fixed abrasive polishing pad, dispensing a polishing composition between the substrate and the polishing pad, and removing the oxide material at a higher removal rate than the nitride material. Polishing compositions containing organic compounds in combination with a polishing enhancement compound and fixed abrasive polishing pads enable modification of the removal rates for polishing different dielectric materials and reduce dishing and loss of adjacent layers.

In another embodiment, the invention provides a chemical mechanical polishing composition for removing dielectric materials, including at least one organic compound, at least one polishing enhancement compound, at least one pH adjusting agent, and deionized water. The combination of organic compounds with the polishing enhancement compound improved polishing selectivity with fixed abrasive pads.

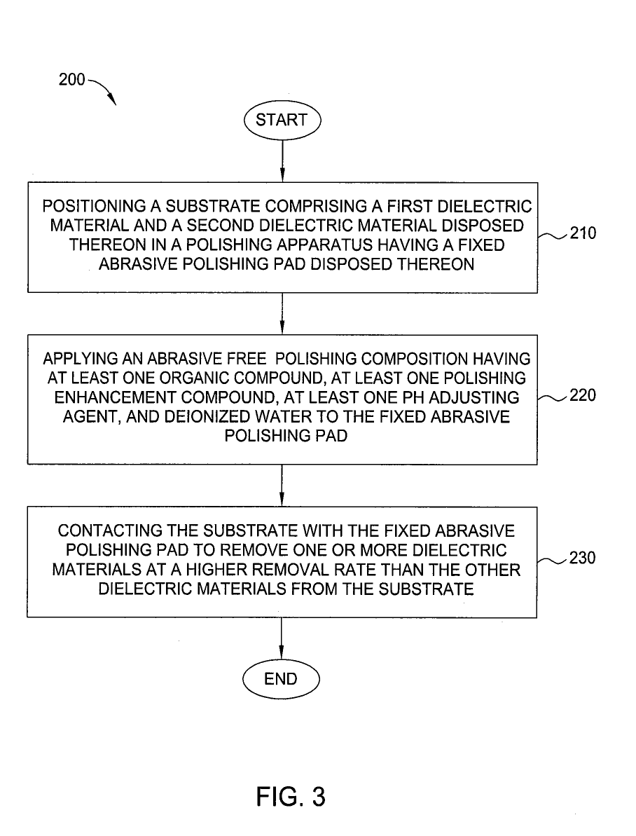

FIG. 3 is a flow chart illustrating one embodiment of a process for planarizing a substrate surface. A method 200 of planarizing a substrate surface using a fixed abrasive polishing pad and a polishing composition containing at least one organic compound and a polishing enhancement compound is provided. A substrate having at least a first and a second dielectric material deposited thereon is positioned in a polishing apparatus having a fixed abrasive polishing pad at step 210. At step 220, a polishing composition, containing at least one organic compound and a polishing enhancement compound, is applied to the fixed abrasive polishing pad disposed on the polishing apparatus, wherein the at least one organic compound and polishing enhancement compound in the polishing composition modifies the removal rates of one or more dielectric materials. The substrate and the fixed abrasive polishing pad are contacted and one or more dielectric materials are removed from the substrate surface at a higher removal rate than the other dielectric materials at step 230.

As used herein “substrate” refers to the object being polished and may include, for example, a silicon based material having materials disposed thereon. The substrates that may be polished by step 210 include shallow trench isolation structures formed in a series of dielectric layers, such as silicon oxide and silicon nitride. The invention contemplates chemical mechanical polishing of dielectric materials conventionally employed in the manufacture of semiconductor devices, for example, silicon dioxide, silicon nitride, silicon oxynitride, phosphorus-doped silicon glass (PSG), boron-doped silicon glass (BSG), boron-phosphorus-doped silicon glass (BPSG), silicon dioxide derived from tetraethyl orthosilicate (TEOS), and silane, which are deposited by various chemical vapor deposition (CVD) techniques, and combinations thereof.

The polishing composition delivered to the fixed abrasive polishing pad at step 220 may include at least one organic compound present in an amount between about 0.5 weight percentage (wt. %) and about 10 wt. % of the polishing composition. A concentration of organic compounds between about 2.5 wt. % and about 4 wt. % is preferably used in the polishing composition. Most preferably, the at least one organic compound may comprise about 2.5 wt. % of the composition. The polishing composition may be delivered or supplied to the fixed abrasive polishing pad at a flow rate of, for example, between about 5 ml/min and about 500 ml/min from a storage medium disposed in or near the CMP system.

Organic compounds useful in the composition include those which may selectively modify the removal rate of one or more dielectric materials in relation to other dielectric materials. In one embodiment, the organic compounds are selected to result in a higher removal rate for silicon oxide material than that for silicon nitride material. Examples of organic compounds include amino acids having amino (NH₂) and carboxyl (—COOH) terminal ends, and derivatives thereof, such as, for example, glycine, proline, arginine, histidine, lysine, and combinations thereof. Examples of other organic compounds include picolinic acid, amphoteric compounds containing amine and carboxylic acid functional groups, such as Amphoteric 400 available from Tomah Products, Inc. of Milton, Wis., hydroxyl acids, for example, gluconic and lactic acid, polyanionic polymers, for example, polyacrylic acid and polyvinylsulfonate.

Polishing enhancement compounds useful in the composition generally include surfactants which may selectively modify the removal rate of one or more dielectric materials in relation to other dielectric materials. Surfactants may be used to increase the dissolution or solubility of materials, such as metals and metal ions or by-products produced during processing, reduce any potential agglomeration of abrasive particles in the polishing composition, and improve chemical stability and reduce decomposition of components of the polishing composition. The one or more surfactants can comprise a concentration between about 0.001 wt. % and about 1 wt. % of the polishing composition. A concentration between about 0.05 wt. % and about 0.1 wt. % may be used in one embodiment of the polishing composition.

The one or more surfactants may include non-ionic surfactants as well as ionic surfactants including anionic surfactants, cationic surfactants, amphoteric surfactants, and ionic surfactants having more than one ionic functional group, such as Zwitter-ionic surfactants. Dispersers or dispersing agents are considered to be surfactants as surfactants are used herein. Compositions containing the polymeric abrasives are stable over a broad pH range and are not prone to aggregating to each other, which allow the abrasives to be used with reduced or no surfactant or no dispersing agent in the composition.

Examples of polishing enhancement compounds generally include anionic surfactants, such as DuPont™ Zonyl® FS-610, non-ionic surfactants, such as DuPont™ Zonyl® FSN, cationic surfactants, such as cetyl pyridinium bromide hydrate, and amphoteric surfactants, such as Amphoteric 400. Additional non-ionic fluorosurfactants include: 3M™ Novec™ FC-4430 and PolyFox™ PF-151N and PF-154N available from Omnova Solutions, Inc of Fairlawn, Ohio.

The polishing composition may also include at least one pH adjusting agent to adjust the pH of the polishing composition to improve polishing performance, such as by allowing a positive or negative charge to be developed on the one or more materials disposed on a substrate surface and attract the appropriately charged organic amino acid compounds. The at least one pH adjusting agent in the composition may be added to adjust the pH level of the composition to between about 4 and about 12. For example, a pH-adjusting agent may be added to the composition in an amount sufficient to produce a pH between about 7 and about 11, for example, a pH of about 10.5. The at least one pH adjusting agent may comprise bases such as potassium hydroxide (KOH) and ammonium hydroxide or acids such as nitric acid or sulfuric acid.

The at least one pH adjusting agent may serve as a pad lubricant or a coolant and may increase or decrease the hydration of the silicon-based dielectric materials resulting in the formation of silanol (Si—OH) groups, which enhance removal of materials from the substrate surface. The at least one pH adjusting agent also affects selective formation of certain complexes between the polishing composition and one or more surface dielectric materials and thus affects removal rates of different surface dielectric materials. For example, an acidic pH increases the formation of silanol on silicon oxide and increases the ability of the polishing composition to complex with the silicon oxide material but not the silicon nitride material.

One possible mechanism for the polishing composition to work with fixed abrasive CMP is that the at least one organic compound may complex with silanol (Si—OH) surface groups of the silicon nitride film and suppress removal of the silicon nitride film. Another possible mechanism is that the at least one organic compound in the polishing composition modifies the removal rates of the dielectric materials by forming a removal resistant or passivation layer on at least one material on the substrate surface and this modification of removal rates is favored by, in this case, an increasing pH.

An example of a polishing composition includes between about 0.5 wt. % and about 10 wt. % of proline, for example, about 2.5 wt. % proline, between about 0.0001 to about 1 wt. % of a surfactant, for example, about 0.05 wt. % of a fluorosurfactant, and potassium hydroxide as a pH adjusting agent in a sufficient amount to produce a pH level of about 10.5. A fixed abrasive polishing pad containing ceria-based abrasives in an equivalent concentration between about 1 wt. % and about 50 wt. % of the polishing pad may be used with the polishing composition to remove material from the substrate surface.

At step 230, the substrate and the fixed abrasive polishing pad are contacted and one dielectric material is removed at a higher removal rate than the other dielectric material from the substrate surface. The material may be removed at a rate between about 50 Å/min and about 5000 Å/min. In one embodiment, a removal rate ratio, or selectivity, of the first material, such as silicon oxide, to the second material, such as silicon nitride, of about 10:1 or greater may be achieved through the use of the organic compounds in a composition described herein. In another embodiment, a removal rate of first material to second material from about 100:1 or greater to about 1200:1 or greater may be achieved from the processes described herein. However, the removal rates and removal rate ratios can vary with the processing parameters and polishing composition used.

An example of a polishing process at step 230 includes moving the polishing pad relative to the substrate at a rate between about 10 rpm and about 200 rpm for a polishing pad disposed on a polishing system. The polishing media is moved relative to the substrate at a rate between about 10 rpm and about 100 rpm for a polishing pad disposed on a round or rotatable platen polishing system. A pressure between about 0.5 psi and about 6.0 psi between the substrate and the polishing pad can be used to provide mechanical activity to the polishing process. Alternatively, the invention contemplates polishing the substrate on a variety of polishing platens, such as rotatable platens, rotatable linear platens, and orbital polishing platens.

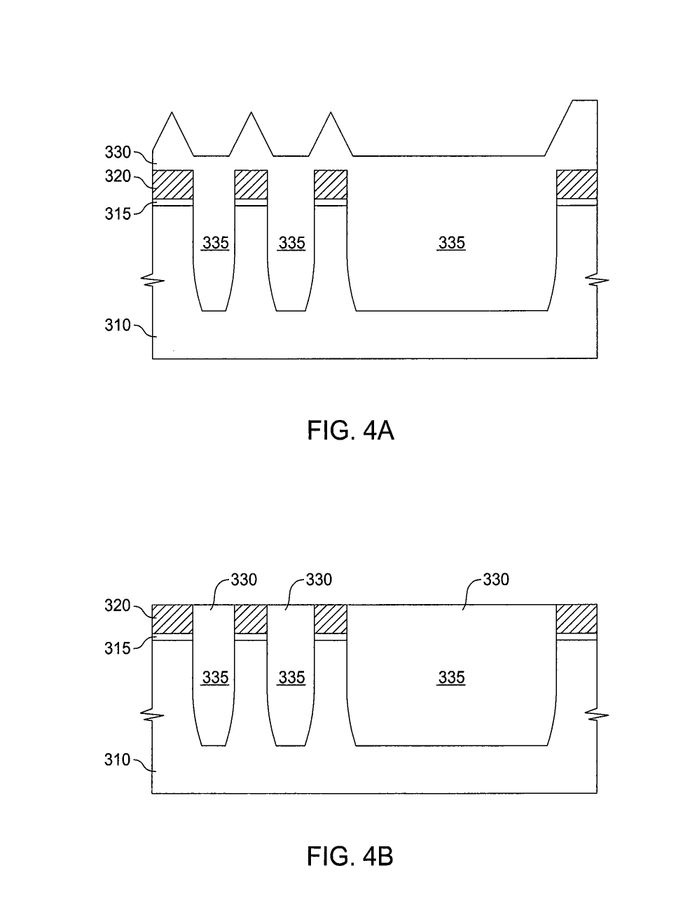

FIGS. 4A and 4B illustrate the selective removal of materials from the substrate surface. FIG. 4A shows an example of substrate materials deposited for the STI formation process. A thermal oxide layer 315 and silicon nitride layer 320 are disposed and patterned over a silicon substrate (or doped silicon layer) 310. The thermal oxide layer 315, silicon nitride layer 320, and silicon substrate 310 are etched to form feature definitions 335, which are then filled by depositing a silicon oxide material 330. The silicon oxide 330 is then polished using the polishing composition described herein to expose the silicon nitride layer. Polishing is continued and the silicon oxide material 330 is removed while the silicon nitride layer 320 remains substantially unpolished as shown in FIG. 4B. Subsequent to ending the polishing process, the silicon nitride layer 320 may be removed prior to further substrate processing.

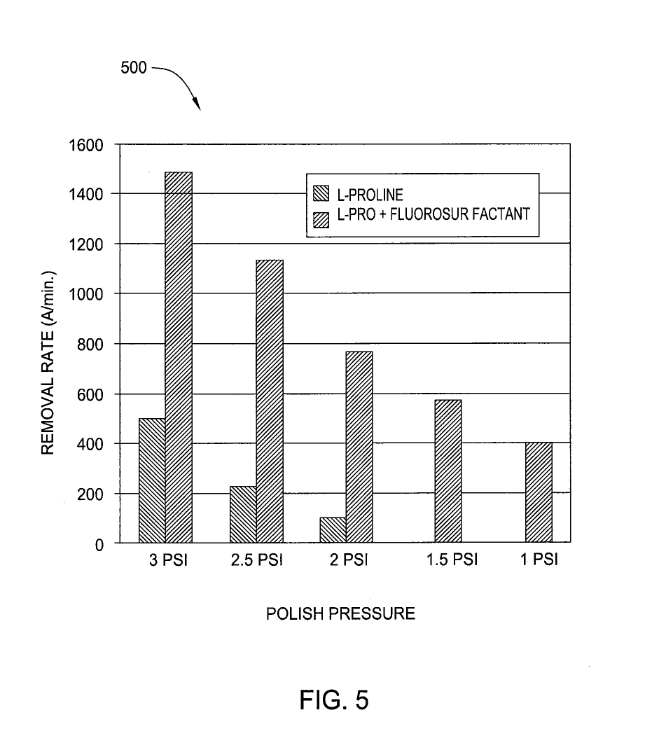

FIG. 5 depicts a plot 500 depicting oxide removal rate as a function of polish pressure for a L-proline/KOH polish fluid and a L-proline/KOH polish fluid to which about 0.05 wt. % of a fluorosurfactant has been added. The comparison of removal rates for L-proline/KOH polish fluid and a L-proline/KOH polish fluid demonstrates that the removal rate typically observed with the L-proline solution at a polish pressure of 3 psi can be achieved at substantially lower polish pressure when a fluorosurfactant is employed. Addition of small amounts of a fluorosurfactant, for example between 0.002 to 0.2 wt. % to a proline based polish fluid dramatically increases the oxide removal rate without altering the pH value or amino acid concentration of the polish fluid. The increased removal rate enables a larger CMP process window than that which is achievable using currently available polish fluids not containing fluorosurfactants. Removal rates equivalent to those achieved using current processes can be obtained at significantly lower polish pressures. The use of lower polish pressures allows for lower platen and head rotational speed without inducing unwanted vibration during polishing and improved within-wafer non-uniformities can be achieved at lower polish pressures since the subpad rebound effect is reduced when lower retaining ring/polish pressures are used.

Addition of at least one organic compound, for example, an amino acid, and a polishing enhancement compound, for example a surfactant, at the proper concentration and pH vastly enhances the performance and flexibility of fixed abrasive CMP. The silicon oxide removal rate is greatly increased while the silicon nitride removal rate is retarded. This enhancement enables shorter polishing times, increased throughput, polishing of thicker overburden substrates, polishing of substrates with a range of feature sizes and densities (e.g., logic applications), improved within-wafer and within-die uniformities, minimized dishing and silicon nitride loss, improved wafer-to-wafer polishing stability, decreased performance degradation due to overpolish, and improved pad wetting.

### EXAMPLES

An example of a polishing process described herein comprises delivering a polishing composition to a fixed abrasive polishing pad containing ceria abrasive particles at a flow rate between 50 ml/min and about 500 ml/min, the polishing composition including between about 0.5 wt. % and about 10 wt. % of proline, for example, about 2.5 wt. % proline, about 0.0001 to about 1 wt. % of a surfactant, for example about 0.05 wt. % of surfactant, deionized water, and potassium hydroxide as a pH adjusting agent in a sufficient amount to produce a pH level between about 10.0 and 12, for example, a pH of about 10.5. A polishing pressure between about 1 and about 6 psi, and a polishing speed between about 10 rpm and about 100 rpm for a polishing duration between about 30 seconds and about 300 seconds may be used to planarize a substrate.

The above-specified components and processing parameters are illustrative and should not be construed as limiting the invention. It is contemplated that the compounds and concentrations used may be varied to provide desired removal rates of 100 Å/min or higher, desired selectivity to stop-on-planar, desired selectivity to stop-on-nitride, and the nature and amount of the desired materials to be removed from the substrate surface. As an example, steps 210, 220, and 230 in FIG. 3 may be performed as part of one continuous operation, or two or more distinct operations. For example, the invention contemplates that different steps may be performed on one or more platens, or portions of some process steps may be performed on different platens.

The invention also contemplates modification of other processes and compositions for shallow trench isolation substrates including the processes and compositions described in U.S. Pat. No. 7,063,597, issued Jun. 20, 2006, entitled POLISHING PROCESSES FOR SHALLOW TRENCH ISOLATION SUBSTRATES and U.S. Patent Application Publication No. 2003/0176151, published Sep. 18, 2003, entitled STI POLISH ENHANCEMENT USING FIXED ABRASIVES WITH AMINO ACID ADDITIVES, which are both herein incorporated by reference to the extent they do not conflict with the current specification. For example, the process including a first step using a slurry on a first platen to remove the bulk of the oxide overburden, a second step involving a fixed abrasive polish on a second platen to complete the planarization process, and a particle rinse step may be modified with the current invention.

The addition of the polishing enhancement composition provides increased flexibility in establishing polish processing parameters. For example, increased oxide removal rates may be achieved without increasing polishing speed and/or downforce conditions.

In another embodiment a concentrated version of the polishing composition is provided. Polishing compositions for fixed abrasive CMP contain mostly water with small amounts of specific chemicals added to enhance polish selectivity and/or to enhance oxide removal performance. For example, one embodiment of a polishing composition contains a selectivity-enhancing additive such as proline in a concentration of between about 2 to 4 wt. %. Surfactants may have a concentration of about 0.1 wt. %. Solution pH is adjusted by addition of less than 1 wt. % of a concentrated base such as KOH. Water is by far the dominant component of the polishing composition (95 to 98% of the total fluid volume). It is more cost effective to ship a concentrated version that can be diluted to the correct strength at the customer's site.

In one embodiment a concentrated polishing composition that is at least 5 times more concentrated than the polishing composition used for polishing wafers with fixed abrasive CMP is provided. In another embodiment, the concentrated polishing composition is at least ten times more concentrated than the polishing composition. In certain embodiments, the L-proline concentration in the polishing composition used for polishing wafers is 2.5 to 4 g per 100 ml water. For the concentrated polishing composition which is five times more concentrated than the polishing composition, the concentration of L-proline would increase, for example, to 12.5 to 20 g per 100 ml. For the concentrated polishing composition which is ten times more concentrated than the polishing composition, the concentration of L-proline would increase to 25 to 40 g per 100 ml, which is well below the literature value of 162 g per 100 ml for water solubility of proline (25° C.). The concentrated polishing composition contains about 1 % flourosurfactant.

KOH is used to adjust fluid pH to within the range of 10 to 11, with 10.5 being most common. Proline acts as a pH buffer in this range, so that substantially more KOH must be added as the target pH increases (10→11) and/or as the proline concentration increases (2.5→4 wt. %). The typical KOH concentration in the polish fluid is about 0.25%, ranging up to about 0.9% in the high pH, high proline concentration case. At 10× concentration these values would be 2.5 to 9%. Thus, all of the polish fluid components are well within the solubility or dispersion limits for a 10× concentrated solution.

While the foregoing is directed to embodiments of the present invention, other and further embodiments of the invention may be devised without departing from the basic scope thereof, and the scope thereof is determined by the claims that follow.

1. A method of selectively removing a dielectric disposed on a substrate having a first dielectric material and a second dielectric material disposed thereon, comprising:
positioning the substrate in proximity with a fixed abrasive polishing pad;
dispensing an abrasive free polishing composition having at least one organic compound and at least one polishing enhancement compound therein between the substrate and the polishing pad; and
selectively polishing the second dielectric material relative to the first dielectric material.

2. The method of claim 1, wherein the at least one polishing enhancement compound is a fluorosurfactant.

3. The method of claim 2, wherein the at least one organic compound comprises an amino acid selected from a group consisting of glycine, proline, arginine, histidine, lysine, and picolinic acid.

4. The method of claim 1, wherein the polishing composition further comprises at least one pH adjusting agent and deionized water.

5. The method of claim 1, wherein the substrate includes a shallow trench isolation structure comprising the first and second dielectric layers.

6. The method of claim 1, wherein the first dielectric material is silicon nitride and the second dielectric material is silicon oxide.

7. The method of claim 6, wherein the silicon oxide and the silicon nitride are removed at a removal rate ratio of about 10:1 or greater.

8. A method of selectively removing an oxide material disposed on a nitride material, comprising:
positioning the substrate in proximity with a fixed abrasive chemical mechanical polishing pad;
dispensing an abrasive free polishing composition having at least one organic compound, at least one fluorosurfactant, at least one pH adjusting agent, and deionized water, between the substrate and the polishing pad; and
removing the oxide material and the nitride material at a removal rate ratio of the oxide material to the nitride material between about 10:1 or greater.

9. The method of claim 8, wherein the oxide material is silicon oxide and the nitride material is silicon nitride.

10. The method of claim 8, wherein the oxide material and the nitride material are removed at a removal rate ratio of the oxide material to the nitride material from about 100:1 to about 2000:1.

11. The method of claim 8, wherein the at least one organic compound comprises proline.

12. The method of claim 8, wherein the polishing composition comprises between about 0.5 wt. % to about 10 wt. % of the at least one organic compound and between about 0.0001 wt. % to about 1 wt. % of the at least one fluorosurfactant.

13. The method of claim 8, wherein the pH of the polishing composition is between about 7 to about 11.

14. An abrasive free polishing composition for removing dielectric materials using a fixed abrasive polishing pad, the composition initially consisting of:
at least one organic compound;
at least one polishing enhancement compound;
at least one pH adjusting agent; and
deionized water.

15. The composition of claim 14, wherein the at least one polishing enhancement compound is a surfactant.

16. The composition of claim 15, wherein the at least one organic compound is an amino acid selected from a group consisting of glycine, proline, arginine, histidine, lysine, and picolinic acid.

17. The composition of claim 16, wherein the at least one polishing enhancement compound comprises a fluorosurfactant.

18. The composition of claim 15, wherein the surfactant is selected from a group consisting of anionic surfactants, non-ionic surfactants, cationic surfactants, and amphoteric surfactants.

19. The composition of claim 15, wherein the composition has a pH value between about 7 to about 11.

20. The composition of claim 15, wherein the polishing composition comprises between about 0.5 wt. % to about 10 wt. % of the at least one organic compound and between about 0.0001 wt. % to about 1 wt. % of the at least one polishing enhancement compound.
